(19) United States
(12) Patent Application Publication
(10) Pub. No.: US 2011/0256666 A1
(43) Pub. Date: Oct. 20, 2011

(54) THERMOSETTING DIE BOND FILM, DICING DIE BOND FILM AND SEMICONDUCTOR DEVICE

(76) Inventors: Yuki SUGO, Ibaraki-shi (JP); Shumpei TANAKA, Ibaraki-shi (JP); Kouichi INOUE, Ibaraki-shi (JP)

(21) Appl. No.: 13/087,617

(22) Filed: Apr. 15, 2011

(30) Foreign Application Priority Data
Apr. 16, 2010 (JP) 2010-095172

(51) Int. Cl. H01L 21/50; B32B 7/12

(52) U.S. Cl. 438/113; 428/343; 257/E21.499

(57) ABSTRACT

The present invention provides a thermosetting type die bond film that can be preferably broken by tensile force. It is a thermosetting type die bond film used for a method of obtaining a semiconductor element from a semiconductor wafer by forming a reforming region by irradiating the semiconductor wafer with a laser beam and then breaking the semiconductor wafer in the reforming region or a method of obtaining a semiconductor element from a semiconductor wafer by forming grooves that do not reach the backside of the semiconductor wafer on a surface thereof and then exposing the grooves from the backside by grinding the backside of the semiconductor wafer, wherein the elongation rate at break at 25° C. before thermal curing is larger than 40% and 500% or less.

### BACKGROUND OF THE INVENTION

1. Field of the Invention

The present invention relates to a thermosetting die bond film used when a semiconductor element such as a semiconductor chip is adhered and fixed on an adherend such as a substrate or a lead frame. The present invention also relates to a dicing die bond film including the thermosetting die bond film and a dicing film layered to each other. The present invention also relates to a method of manufacturing a semiconductor device using the dicing die bond film.

2. Description of the Related Art

Conventionally, silver paste has been used to bond a semiconductor chip to a lead frame or an electrode member in the step of producing a semiconductor device. The treatment for the sticking is conducted by coating a paste-form adhesive on a die pad of a lead frame, or the like, mounting a semiconductor chip on the die pad, and then setting the paste-form adhesive layer.

However, about the paste-form adhesive, the amount of the coated adhesive, the shape of the coated adhesive, and on the like are largely varied in accordance with the viscosity behavior thereof, a deterioration thereof, and on the like. As a result, the thickness of the formed paste-form adhesive layer becomes uneven so that the reliability in strength of bonding a semiconductor chip is poor. In other words, if the amount of the paste-form adhesive coated on an electrode member is insufficient, the bonding strength between the electrode member and a semiconductor chip becomes low so that in a subsequent wire bonding step, the semiconductor chip is peeled. On the other hand, if the amount of the coated paste-form adhesive is too large, this adhesive flows out to stretch over the semiconductor chip so that the characteristic becomes poor. Thus, the yield or the reliability lowers. Such problems about the adhesion treatment become particularly remarkable with an increase in the size of semiconductor chips. It is therefore necessary to control the amount of the coated paste-form adhesive frequently. Thus, the workability or the productivity is deteriorated.

In this coating step of a paste-form adhesive, there is a method of coating the adhesive onto a lead frame or a forming chip by an independent operation. In this method, however, it is difficult to make the paste-form adhesive layer even. Moreover, an especial machine or a long time is required to coat the paste-form adhesive. Thus, a dicing film which makes a semiconductor wafer to be bonded and held in a dicing step and further gives an adhesive layer, for bonding a chip, which is necessary for a mounting step is disclosed (see, for example, JP-A-60-57342).

This dicing film has a structure wherein a adhesive layer and an adhesive layer are successively laminated on a supporting substrate. That is, a semiconductor wafer is diced in the state that the wafer is held on the adhesive layer, and then the supporting substrate is extended; the chipped works are peeled together with the adhesive layer; the peeled works are individually collected; and further the chipped works are bonded onto an adherend such as a lead frame through the adhesive layer.

When a dicing die bond film including a dicing film and a die bond film laminated thereon is used and a semiconductor wafer is diced while being held by the die bond film, it is necessary to cut the die bond film and the semiconductor wafer at the same time. However, in a general dicing method using a diamond blade, it is necessary to reduce the cutting speed and costs are increased because there are potential problems such as adhesion of the die bond film with the dicing film due to heat that is generated during dicing, sticking of semiconductor chips due to generation of cutting scraps, and attachment of cutting scraps onto the side of the semiconductor chips.

In recent years, a method of obtaining individual semiconductor chips by forming grooves on a surface of a semiconductor wafer and then performing backside grinding (refer to Japanese Patent Application Laid-Open No. 2003-007649, hereinafter also referred to as a “DBG (Dicing Before Grinding) method) and a method of obtaining individual semiconductor chips by forming a reforming region by irradiating predetermined dividing lines on a semiconductor wafer with a laser beam so that the semiconductor wafer can be easily divided at the predetermined dividing lines and then breaking the semiconductor wafer by applying tensile force (refer to Japanese Patent Application Laid-Open Nos. 2002-192370 and 2003-338467, hereinafter also referred to as “Stealth Dicing (trademark)”) have been proposed. According to these methods, the generation of defects such as chipping can be reduced in the case where the semiconductor wafer is thin and the yield of the semiconductor chip can be improved by narrowing the kerf width.

It is necessary to break the die bond film by applying a tensile force to obtain individual semiconductor chips with a die bond film by the above-described method while the semiconductor wafer is being held by the die bond film. Accordingly, development of a die bond film that can be suitably broken by applying a tensile force has been desired.

An adhesive sheet used for the DBG method and the stealth dicing is disclosed in International Publication No. 2004/109786, the sheet having a breaking strength at 25° C. of 0.1 to 10 MPa and the elongation rate at break of 1 to 40%. However, because the elongation rate at break of the adhesive sheet of International Publication No. 2004/109786 is 40% or less, the adhesive sheet may break faster than the semiconductor wafer when tensile force is applied in application for the stealth dicing, and may be divided on lines that differ from the predetermined dividing lines.

### SUMMARY OF THE INVENTION

The present invention was made in view of the above-described problems, and an object thereof is to provide a thermosetting type die bond film which can be preferably broken by tensile force, and a dicing die bond film.

Another object of the present invention is to provide a method of manufacturing a semiconductor device in which the die bond film can be preferably broken by tensile force.

The present inventors investigated a thermosetting type die bond film and a dicing die bond film in which the thermosetting type die bond film and a dicing film are laminated to solve the above-described conventional problems. As a result, it was found that the die bond film can be preferably broken by tensile force by making the elongation rate at break at 25° C. before thermal curing be larger than 40% and 500% or less, and the present invention was completed.

That is, the thermosetting type die bond film according to the present invention is used for a method of obtaining a semiconductor element from a semiconductor wafer by forming a reforming region by irradiating the semiconductor wafer with a laser beam and then breaking the semiconductor wafer in the reforming region (stealth dicing) or a method of obtaining a semiconductor element from a semiconductor wafer by forming grooves that do not reach the backside of the semiconductor wafer on a surface thereof and then exposing the grooves from the backside by grinding the backside of the semiconductor wafer (DBG method), and in which the elongation rate at break at 25° C. before thermal curing is larger than 40% and 500% or less.

In order to obtain a semiconductor element (for example, a semiconductor chip) from a semiconductor wafer by stealth dicing or a DBG method, the thermosetting type die bond film is broken by applying tensile force thereto. According to the above-described configuration, because the elongation rate at break at 25° C. before thermal curing is larger than 40%, easy breaking can be prevented and the handling property can be improved. Further, because the elongation rate at break is 500% or less, excess elongation of the film when it is extended can be prevented and the film can be broken preferably. Therefore, according to the above-described configuration, because the elongation rate at break at 25° C. before thermal curing is larger than 40% and 500% or less, the die bond film can be preferably broken by tensile force in obtaining a semiconductor element from a semiconductor wafer by stealth dicing or a DBG method. Especially, because the elongation rate at break at 25° C. before thermal curing is larger than 40%, the die bond film and the semiconductor wafer can be broken together at the same time and the die bond film and the semiconductor wafer can be broken certainly at the predetermined dividing lines in obtaining a semiconductor element from the semiconductor wafer by stealth dicing.

In the above-described configuration, the ratio (b/a) of a tensile storage modulus (b) at 25° C. and 10 Hz to a tensile storage modulus (a) at 0° C. and 10 Hz obtained from a dynamic viscoelasticity measurement before thermal curing is preferably 0.15 to 1. The die bond film is conventionally broken by applying tensile force thereto at a low temperature of −20 to 0° C. However, there is a problem that manufacturing efficiency decreases because tensile force cannot be applied continuously until the die bond film comes into a low temperature state. Further, there is also a problem that the temperature upon application of tensile force goes out of the above-described low temperature range due to the ability of the apparatus and the external environment because tensile force is applied at a low temperature that is far from room temperature. Accordingly, there is a desire to break the die bond film under a temperature condition around room temperature (for example, 0 to 25° C.). According to the above-described configuration, the thermosetting type die bond film can be broken stably in the temperature range of 0 to 25° C. by making the ratio (b/a) be 0.15 to 1. As a result, the manufacturing efficiency can be improved.

In the above-described configuration, the tensile storage modulus at 0° C. and 10 Hz obtained from a dynamic viscoelasticity measurement before thermal curing is preferably 2500 to 5000 MPa. By making the tensile storage modulus at 0° C. and 10 Hz obtained from a dynamic viscoelasticity measurement before thermal curing be 2500 MPa or more, the degree of crystallization of the die bond film improves and the breaking property during expansion becomes good. On the other hand, by making the tensile storage modulus at 0° C. and 10 Hz obtained from a dynamic viscoelasticity measurement before thermal curing be 5000 MPa or less, the wafer lamination property of the die bond film improves.

In the above-described configuration, the tensile storage modulus at 25° C. and 10 Hz obtained from a dynamic viscoelasticity measurement before thermal curing is preferably 700 to 2500 MPa. By making the tensile storage modulus at 25° C. and 10 Hz obtained from a dynamic viscoelasticity measurement before thermal curing be 700 MPa or more, the degree of crystallization of the die bond film improves and the breaking property during expansion becomes better. On the other hand, by making the tensile storage modulus at 25° C. and 10 Hz obtained from a dynamic viscoelasticity measurement before thermal curing be 2500 MPa or less, the wafer lamination property of the die bond film improves further.

In the above-described configuration, the glass transition temperature before thermal curing is preferably 25 to 60° C. By making the glass transition temperature before thermal curing be 25 to 60° C., the wafer can be laminated well.

In the above-described configuration, the tensile storage modulus at −20° C. and 10 Hz obtained from a dynamic viscoelasticity measurement before thermal curing is preferably 2000 to 4000 MPa. By making the tensile storage modulus at −20° C. and 10 Hz obtained from a dynamic viscoelasticity measurement before thermal curing be 2000 MPa or more, the degree of crystallization of the die bond film improves and the breaking property during expansion becomes good. On the other hand, by making it be 4000 MPa or less, the wafer lamination property of the die bond film improves.

In the above-described configuration, the loss modulus at 25° C. and 10 Hz obtained from a dynamic viscoelasticity measurement before thermal curing is preferably 400 to 1000 MPa.

By making the loss modulus at 25° C. and 10 Hz obtained from a dynamic viscoelasticity measurement before thermal curing be 400 MPa or more, the degree of crystallization of the die bond film improves and the breaking property during expansion becomes good. On the other hand, by making it be 1000 MPa or less, the wafer lamination property of the die bond film improves.

In the above-described configuration, the die bond film contains an epoxy resin, a phenol resin, and an acrylic resin. Defining the total weight of the epoxy resin and the phenol resin as X and the weight of the acrylic resin as Y, X/(X+Y) is preferably 0.3 or more and less than 0.9. As the content of the epoxy resin and the phenol resin increases, the die bond film can be easily broken and tackiness to the semiconductor wafer decreases. Further, as the content of the acrylic resin increases, workability becomes good because it becomes difficult for the die bond film to crack upon pasting or handling and it becomes difficult for the die bond film to break. By making X/(X+Y) be 0.3 or more, the die bond film and the semiconductor wafer can be broken together at the same time more easily compared to the case where a semiconductor element is obtained from the semiconductor wafer by stealth dicing. By making X/(X+Y) be less than 0.9, the workability can be made good.

The dicing die bond film according to the present invention features that the thermosetting die bond film is laminated on the dicing film including a base and a pressure-sensitive adhesive layer laminated thereon to solve the problems.

The method of manufacturing a semiconductor device according to the present invention employs the above-described dicing die bond film, and includes the steps of: forming a reforming region on predetermined dividing lines by irradiating the predetermined dividing lines of the semiconductor wafer with a laser beam, pasting the semiconductor wafer after the formation of the reforming region to the dicing die bond film, forming a semiconductor element by breaking the semiconductor wafer and the die bond film that constitutes the dicing die bond film together at the predetermined dividing lines by applying tensile force to the dicing die bond film so that the expansion speed becomes 100 to 400 mm/sec and the expansion amount becomes 6 to 12% under a condition of 0 to 25° C., picking up the semiconductor element together with the die bond film, and die bonding the picked up semiconductor element to an adherend with the die bond film in between.

According to the above-described configuration, the semiconductor element is formed by breaking the semiconductor wafer and the die bond film that constitutes the dicing die bond film at the predetermined dividing lines by applying tensile force to the dicing die bond film so that the expansion speed becomes 100 to 400 mm/sec and the expansion amount becomes 6 to 12% under a condition of 0 to 25° C. Because it is not necessary to put the dicing die bond film into a low temperature state (less than 0° C.), a semiconductor element can be formed by pasting the semiconductor wafer after the formation of a reforming region to the dicing die bond film and breaking the semiconductor wafer and the die bond film at the predetermined dividing lines by immediately applying tensile force. As a result, the manufacturing efficiency can be improved. Further, because tensile force is applied under a condition of 0 to 25° C. that is a temperature around room temperature, it is difficult for the temperature upon application of tensile force to go out of the range of 0 to 25° C. due to the ability of the apparatus and the external environment. As a result, the yield can be improved.

According to the above-described configuration, because the expansion speed is 100 mm/sec or more, the semiconductor wafer and the die bond film can be substantially simultaneously broken easily. Because the expansion speed is 400 mm/sec or less, the dicing film can be prevented from breaking.

According to the above-described configuration, because the expansion amount is 6% or more, the semiconductor wafer and the die bond film can be easily broken. Because the expansion amount is 12% or less, the dicing film can be prevented from breaking.

The method of manufacturing a semiconductor device according to the present invention employs the above-described dicing die bond film, and includes the steps of: forming grooves that do not reach the backside of the semiconductor wafer on a surface thereof, exposing the grooves from the backside by grinding the backside of the semiconductor wafer, pasting the semiconductor wafer with the grooves exposed from the backside to the dicing die bond film, forming a semiconductor element by breaking the die bond film that constitutes the dicing die bond film by applying tensile force to the dicing die bond film so that the expansion speed becomes 100 to 400 mm/sec and the expansion amount becomes 6 to 12% under a condition of 0 to 25° C., picking up the semiconductor element together with the die bond film, and die bonding the picked up semiconductor element to an adherend with the die bond film in between.

According to the above-described configuration, a semiconductor element is formed by breaking the die bond film that constitutes the dicing die bond film by applying tensile force to the dicing die bond film so that the expansion speed becomes 100 to 400 mm/sec and the expansion amount becomes 6 to 12% under a condition of 0 to 25° C. Because it is not necessary to put the dicing die bond film into a low temperature state (less than 0° C.), the semiconductor element can be formed by pasting the semiconductor wafer with the grooves exposed to the dicing die bond film and then breaking the die bond film by immediately applying tensile force. As a result, the manufacturing efficiency can be improved. Further, because tensile force is applied under a condition of 0 to 25° C. that is a temperature around room temperature, it is difficult for the temperature upon application of tensile force to go out of the range of 0 to 25° C. due to ability of the apparatus and the external environment. As a result, the yield can be improved.

According to the above-described configuration, because the expansion speed is 100 mm/sec or more, the die bond film can be easily broken. Because the expansion speed is 400 mm/sec or less, the dicing film can be prevented from breaking.

According to the above-described configuration, because the expansion amount is 6% or more, the die bond film can be easily broken. Because the expansion amount is 12% or less, the dicing film can be prevented from breaking.

### BRIEF DESCRIPTION OF THE DRAWINGS

FIG. 1 is a schematic sectional view showing a dicing die bond film according to one embodiment of the present invention;

FIG. 2 is a schematic sectional view showing a dicing die bond film according to another embodiment of the present invention;

FIG. 3 is a schematic sectional view for explaining one method of manufacturing a semiconductor device according to the present embodiment;

FIG. 4 is a schematic sectional view for explaining the method of manufacturing a semiconductor device according to the present embodiment;

FIGS. 5A and 5B are schematic sectional views for explaining the method of manufacturing a semiconductor device according to the present embodiment;

FIG. 6 is a schematic sectional view for explaining the method of manufacturing a semiconductor device according to the present embodiment;

FIGS. 7A and 7B are schematic sectional views for explaining another method of manufacturing a semiconductor device according to the present embodiment;

FIG. 8 is a schematic sectional view for explaining the different method of manufacturing a semiconductor device according to the present embodiment; and

### DESCRIPTION OF THE REFERENCE NUMERALS

1 base
2 pressure-sensitive adhesive layer
3, 3′ die bond film (thermosetting type die bond film)
4 semiconductor wafer
5 semiconductor chip
6 adherend
7 bonding wire
8 sealing resin
10, 12 dicing die bond film
11 dicing film

### DESCRIPTION OF THE EMBODIMENTS

### Dicing Die Bond Film

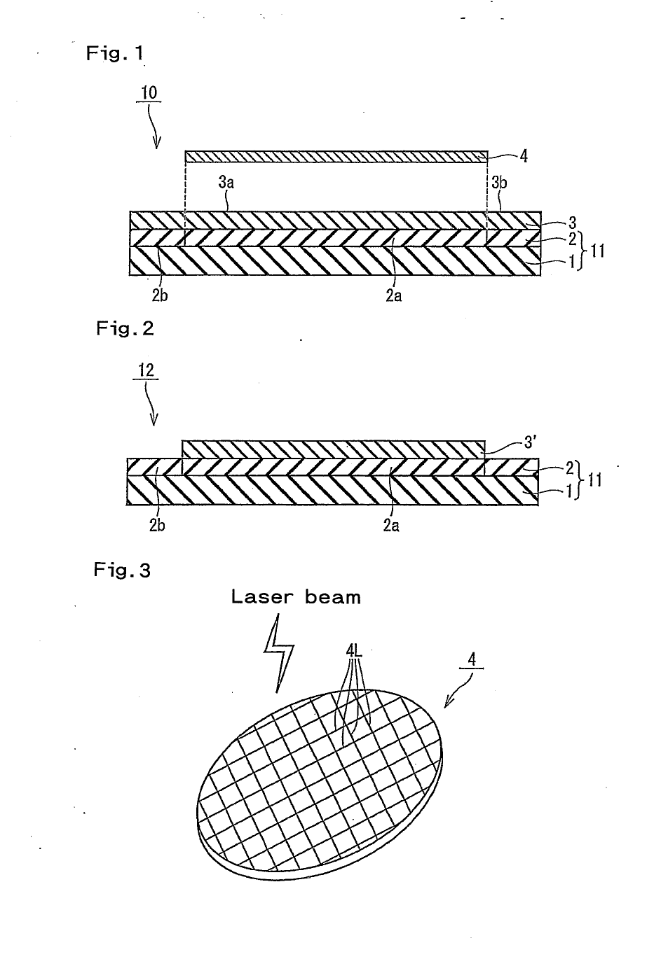

The dicing die bond film of the present invention is explained below. FIG. 1 is a schematic sectional view showing a dicing die bond film according to one embodiment of the present invention. FIG. 2 is a schematic sectional view showing a dicing die bond film according to another embodiment of the present invention.

As shown in FIG. 1, a dicing die bond film 10 has a constitution in which a die bond film 3 is layered on a dicing film 11. The dicing film 11 is constituted by layering a pressure-sensitive adhesive layer 2 on a base material 1, and the die bond film 3 is provided on the adhesive layer 2. As shown in FIG. 2, the present invention may have a constitution such that a die bond film 3′ is formed only at the semiconductor wafer pasting part.

The base material 1 preferably has ultraviolet transmissivity and is a base body for strength of the dicing die bond films 10 and 12. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

Further, the material of the base material 1 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 2 and the die bond films 3, 3′ is reduced by thermally shrinking the base material 1 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 1 in order to improve adhesiveness, holding properties, etc. with the adjacent layer. The same type or different type of base material can be appropriately selected and used as the base material 1, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 1 in order to give an antistatic function to the base material 1. The base material 1 may be a single layer or a multi layer of two or more types.

The thickness of the base material 1 can be appropriately decided without limitation particularly. However, it is generally about 5 to 200 μm.

The pressure-sensitive adhesive layer 2 is constituted by containing a ultraviolet curable pressure sensitive adhesive. The ultraviolet curable pressure sensitive adhesive can easily decrease its adhesive strength by increasing the degree of crosslinking by irradiation with ultraviolet. By radiating only a part 2a corresponding to the semiconductor wafer pasting part of the pressure-sensitive adhesive layer 2 shown in FIG. 2, a difference of the adhesive strength to another part 2b can be also provided.

Further, by curing the ultraviolet curable pressure-sensitive adhesive layer 2 with the die bond film 3′ shown in FIG. 2, the part 2a in which the adhesive strength is remarkably decreased can be formed easily. Because the die bond film 3′ is pasted to the part 2a in which the adhesive strength is decreased by curing, the interface of the part 2a of the pressure-sensitive adhesive layer 2 and the die bond film 3′ has a characteristic of being easily peeled during pickup. On the other hand, the part not radiated by ultraviolet rays has sufficient adhesive strength, and forms the part 2b.

As described above, in the pressure-sensitive adhesive layer 2 of the dicing die bond film 10 shown in FIG. 1, the part 2b formed by a non-cured ultraviolet curable pressure sensitive adhesive sticks to the die bond film 3, and the holding force when dicing can be secured. In such a way, the ultraviolet curable pressure sensitive adhesive can support the die bond film 3 for fixing the semiconductor chip onto an adherend such as a substrate with good balance of adhesion and peeling. In the pressure-sensitive adhesive layer 2 of the dicing die bond film 11 shown in FIG. 2, a dicing ring can be fixed to the part 2b.

The ultraviolet curable pressure sensitive adhesive that is used has a ultraviolet curable functional group of a radical reactive carbon-carbon double bond, etc., and adherability. Examples of the ultraviolet curable pressure sensitive adhesive are an added type ultraviolet curable pressure sensitive adhesive in which a ultraviolet curable monomer component or an oligomer component is compounded into an acryl pressure sensitive adhesive or a rubber pressure sensitive adhesive.

The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer (s) to be used is preferably 40% or less by weight of all the monomer components.

For crosslinking, the acrylic polymer can also contain multifunctional monomers if necessary as the copolymerizable monomer component. Such multifunctional monomers include hexane dioldi(meth)acrylate, (poly)ethyleneglycoldi(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 30000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 70 to 150 parts by weight based on 100 parts by weight of the base polymer such as an acryl polymer constituting the pressure sensitive adhesive.

Further, besides the added type ultraviolet curable pressure sensitive adhesive described above, the ultraviolet curable pressure sensitive adhesive includes an internal ultraviolet curable pressure sensitive adhesive using an acryl polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods.

The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond.

However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl (2-hydroxy-2-propyl) ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the ultraviolet curing type pressure-sensitive adhesive which is used in the formation of the pressure-sensitive adhesive layer 2 include such as a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound.

The method of forming the part 2a in the pressure-sensitive adhesive layer 2 includes a method of forming the ultraviolet curable pressure-sensitive adhesive layer 2 on the base material 1 and then radiating the part 2a with ultraviolet partially and curing. The partial ultraviolet irradiation can be performed through a photo mask in which a pattern is formed which is corresponding to a part 3b, etc. other than the semiconductor wafer pasting part 3a. Further, examples include a method of radiating in a spot manner and curing, etc. The formation of the ultraviolet curable pressure-sensitive adhesive layer 2 can be performed by transferring the pressure-sensitive adhesive layer provided on a separator onto the base material 1. The partial ultraviolet curing can be also performed on the ultraviolet curable pressure-sensitive adhesive layer 2 provided on the separator.

In the pressure-sensitive adhesive layer 2 of the dicing die bond film 10, the ultraviolet irradiation may be performed on a part of the pressure-sensitive adhesive layer 2 so that the adhesive strength of the part 2a becomes smaller than the adhesive strength of other parts 2b. That is, the part 2a in which the adhesive strength is decreased can be formed by using those in which the entire or a portion of the part other than the part corresponding to the semiconductor wafer pasting part 3a on at least one face of the base material 1 is shaded, forming the ultraviolet curable pressure-sensitive adhesive layer 2 onto this, then radiating ultraviolet, and curing the part corresponding the semiconductor wafer pasting part 3a. The shading material that can be a photo mask on a supporting film can be manufactured by printing, vapor deposition, etc. Accordingly, the dicing die bond film 10 of the present invention can be produced with efficiency.

The thickness of the pressure-sensitive adhesive layer 2 is not particularly limited. However, it is preferably about 1 to 50 μm from the viewpoint of preventing chipping of the chip cut surface, compatibility of fixing and holding of the adhesive layer, and the like. It is preferably 2 to 30 μm, and further preferably 5 to 25 μm.

The tensile strength of the portion 2a that corresponds to the semiconductor wafer pasting portion of the dicing film 11 at 25° C. during expansion is preferably 15 to 80 N and more preferably 20 to 70 N. The tensile strength is the strength at 10% elongation of a sample of 25 mm in width at a distance between chucks of 100 mm and a tensile speed of 300 mm/min. The elongation at yield point of the portion 2a that corresponds to the semiconductor wafer pasting portion of the dicing film 11 at 25° C. during expansion is preferably 80% or more, and more preferably 85% or more. The elongation at yield point is the elongation rate at the yield point of a stress-strain curve that is obtained by performing measurement on a sample of 10 mm in width at a distance between chucks of 50 mm and a tensile speed of 300 mm/min. By making the tensile strength and the elongation at the yield point of the dicing film 11 at 25° C. be in the above-described ranges, the dicing film 11 is prevented from breaking in a step of breaking the die bond films 3 and 3′ by applying tensile force to the dicing die bond film 12 (a chip forming step that is described later).

The elongation rate at break of the die bond films 3 and 3′ at 25° C. before thermal curing is larger than 40% and 500% or less. Because the elongation rate at break is larger than 40% and 500% or less, the die bond films 3 and 3′ can be suitably broken by tensile force in a step of breaking the die bond films 3 and 3′ by applying tensile force to the dicing die bond film 12 (a chip forming step that is described later). Especially, because the elongation rate at break at 25° C. before thermal curing is larger than 40%, the die bond films 3 and 3′ and a semiconductor wafer 4 can be simultaneously broken when the tensile force is applied to the dicing die bond film 12 to obtain a semiconductor chip 5 from the semiconductor wafer 4 by stealth dicing, and the die bond films 3 and 3′ and the semiconductor wafer 4 can be broken certainly at a predetermined dividing lines 4L. The elongation rate at break is preferably larger than 43% and 500% or less, and more preferably larger than 60% and 450% or less. When the die bond films 3 and 3′ are long, the elongation rate at break has only to satisfy the above-described numerical range in at least one direction of the flow direction (MD) and the width direction (TD).

The ratio (b/a) of the tensile storage modulus (b) at 25° C. and 10 Hz to the tensile storage modulus (a) at 0° C. and 10 Hz of the die bond films 3 and 3′ obtained from a dynamic viscoelasticity measurement before thermal curing is preferably 0.15 to 1, more preferably 0.18 to 0.95, and further preferably 0.2 to 0.9. The die bond films 3 and 3′ are conventionally broken by applying tensile force thereto at a low temperature of −20 to 0° C. However, there has been a problem that manufacturing efficiency decreases because tensile force cannot be applied continuously until the die bond films 3 and 3′ come into a low temperature state. Further, there is a problem that the set temperature goes out of the above-described low temperature range due to the ability of the apparatus and the external environment because tensile force is applied at a low temperature that is far from room temperature. Accordingly, there is a desire to break the die bond films 3 and 3′ under a temperature condition around room temperature (for example, 0 to 25° C.). By making the ratio (b/a) be 0.15 to 1, the die bond films 3 and 3′ can be broken stably in the temperature range of 0 to 25° C. As a result, the manufacturing efficiency can be improved.

The tensile storage modulus of the die bond films 3 and 3′ at 0° C. and 10 Hz obtained from a dynamic viscoelasticity measurement before thermal curing is preferably 2500 to 5000 MPa, more preferably 2550 to 4000 MPa, and further preferably 2600 to 3800 MPa. By making the tensile storage modulus at 0° C. and 10 Hz obtained from a dynamic viscoelasticity measurement before thermal curing be 2500 MPa or more, the degree of crystallization of the die bond film improves and the breaking property during expansion becomes good. On the other hand, by making the tensile storage modulus at 0° C. and 10 Hz obtained from a dynamic viscoelasticity measurement before thermal curing be 5000 MPa or less, the wafer lamination property of the die bond film improves.

The tensile storage modulus of the die bond films 3 and 3′ at 25° C. and 10 Hz obtained from a dynamic viscoelasticity measurement before thermal curing is preferably 700 to 2500 MPa, more preferably 800 to 2400 MPa, and further preferably 900 to 2300 MPa. By making the tensile storage modulus at 25° C. and 10 Hz obtained from a dynamic viscoelasticity measurement before thermal curing be 700 MPa or more, the degree of crystallization of the die bond film improves and the breaking property during expansion becomes better. On the other hand, by making the tensile storage modulus at 25° C. and 10 Hz obtained from a dynamic viscoelasticity measurement before thermal curing be 2500 MPa or less, the wafer lamination property of the die bond film improves further.

The tensile storage modulus of the die bond films 3 and 3′ at −20° C. and 10 Hz obtained from a dynamic viscoelasticity measurement before thermal curing is preferably 2000 to 4000 MPa, more preferably 2500 to 3800 MPa, and further preferably 2800 to 3600 MPa. By making the tensile storage modulus at −20° C. and 10 Hz obtained from a dynamic viscoelasticity measurement before thermal curing be 2000 MPa or more, the degree of crystallization of the die bond film improves and the breaking property during expansion becomes good. On the other hand, by making it be 4000 MPa or less, the wafer lamination property of the die bond film improves. The tensile storage modulus obtained from a dynamic viscoelasticity measurement is a value that can be obtained using a sample of 5 mm in width and 400 μmin thickness at a distance between chucks of 20 mm and using a dynamic viscoelasticity measurement apparatus (RSA III manufactured by Rheometric Scientific FE, Ltd.) under a condition of a temperature rise rate of 5° C./min.

The loss modulus of the die bond films 3 and 3′ at 25° C. and 10 Hz obtained from a dynamic viscoelasticity measurement before thermal curing is preferably 400 to 1000 MPa, more preferably 450 to 950 MPa, and further preferably 500 to 900 MPa. By making the loss modulus at 25° C. and 10 Hz obtained from a dynamic viscoelasticity measurement before thermal curing be 400 MPa or more, the degree of crystallization of the die bond film improves and the breaking property during expansion becomes good. On the other hand, by making it be 1000 MPa or less, the wafer lamination property of the die bond film improves. The loss modulus obtained from a dynamic viscoelasticity measurement is a value that can be obtained using a sample of 5 mm in width and 400 μm in thickness at a distance between chucks of 20 mm and using a dynamic viscoelasticity measurement apparatus (RSA III manufactured by Rheometric Scientific FE, Ltd.) under a condition of a temperature rise rate of 5° C./min.

The ratio (c/d) of a tensile storage modulus (c) at 0° C. and 900 Hz to a tensile storage modulus (d) at 25° C. and 10 Hz of the die bond films 3 and 3′ obtained from a dynamic viscoelasticity measurement before thermal curing is preferably 0.72 to 0.85. By making the ratio (c/d) be 0.72 or more, the degree of crystallization of the die bond film improves, the film becomes brittle easily during expansion, and the breaking property improves. By making the ratio (c/d) be 0.85 or less, the wafer lamination property of the die bond film improves.

The tensile storage modulus of the die bond films 3 and 3′ at 0° C. and 900 Hz obtained from a dynamic viscoelasticity measurement before thermal curing is preferably 5000 to 6800 MPa, more preferably 5100 to 6700 MPa, and further preferably 5200 to 6600 MPa. By making the tensile storage modulus at 0° C. and 900 Hz obtained from a dynamic viscoelasticity measurement before thermal curing be 5000 MPa or more, the degree of crystallization of the die bond film improves, the film becomes brittle easily during expansion, and the breaking property improves. On the other hand, by making the tensile storage modulus at 0° C. and 900 Hz obtained from a dynamic viscoelasticity measurement before thermal curing be 6800 MPa or less, the wafer lamination property of the die bond film improves.

The tensile storage modulus of the die bond films 3 and 3′ at 25° C. and 900 Hz obtained from a dynamic viscoelasticity measurement before thermal curing is preferably 3000 to 5500 MPa, more preferably 3600 to 5450 MPa, and further preferably 4000 to 5400 MPa. By making the tensile storage modulus at 25° C. and 900 Hz obtained from a dynamic viscoelasticity measurement before thermal curing be 3000 MPa or more, the degree of crystallization of the die bond film improves, the film becomes brittle easily during expansion, and the breaking property improves. On the other hand, by making the tensile storage modulus at 25° C. and 900 Hz obtained from a dynamic viscoelasticity measurement before thermal curing be 5500 MPa or less, the wafer lamination property of the die bond film improves.

The lamination structure of the die bond film is not especially limited, and examples thereof include a single layer structure of an adhesive layer such as the die bond films 3 and 3′ (refer to FIGS. 1 and 2) and a multi-layered structure in which an adhesive layer is formed on one side or both sides of a core member. Examples of the core member include films (such as polyimide film, polyester film, polyethylene terephthalate film, polyethylene naphthalate film, and polycarbonate film); resin substrates which are reinforced with glass fiber or plastic nonwoven finer; silicon substrates; and glass substrates. In a die bond film having a multilayered structure, the elongation rate at break, the tensile storage modulus, the loss modulus, and the like of the whole die bond film having a multilayered structure have only to be in the above-described numerical ranges.

The adhesive composition constituting the die bond films 3, 3′ include those in which a thermoplastic resin is used in combination with a thermosetting resin.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylic acid ester copolymer, a polybutadiene resin, a polycarbonate resin, a thermoplastic polyimide rein, a polyamide resin such as 6-nylon or 6,6-nylon, a phenoxy resin, an acrylic resin, a saturated polyester resin such as PET or PBT, a polyamideimide resin, and a fluorine resin. These thermoplastic resins may be used either alone or in combination of two or more kinds of them. Among these thermoplastic resins, the acrylic resin is especially preferable since it has fewer ionic impurities and high heat resistance, such that reliability of the semiconductor element can be secured.

The acrylic resin is not especially limited, and examples thereof include a polymer (an acrylic copolymer) containing one kind or two or more kinds of acrylic or methacrylic acid esters having a linear or branched alkyl group of 30 or less carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Among the acrylic resins, the acrylic copolymer is especially preferable for the purpose of improving the cohesive strength. Examples of the acrylic copolymer include a copolymer of ethyl acrylate and methyl methacrylate, a copolymer of acrylic acid and acrylonitrile, and a copolymer of butyl acrylate and acrylonitrile.

The glass transition temperature (Tg) of the acrylic resin is preferably −30 to 30° C., and more preferably −20 to 15° C. By making the glass transition temperature of the acrylic resin be −30° C. or more, the die bond film becomes hard and the breaking property improves, and by making it 30° C. or less, the wafer lamination property at a low temperature improves. Examples of the acrylic resin having a glass transition temperature of −30 to 30° C. include SG-708-6 (glass transition temperature: 6° C.), SG-790 (glass transition temperature: −25° C.), WS-023 (glass transition temperature: −5° C.), SG-80H (glass transition temperature: 7.5° C.), and SG-P3 (glass transition temperature: 15° C.) manufactured by Nagase ChemteX Corporation.

Other monomers that form the polymer are not especially limited, and examples thereof include carboxyl group-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methyl acrylate; sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl(meth)acrylate, and (meth)acryloyloxynaphthalenesulfonic acid; and phosphate group-containing monomers such as 2-hydroxyethylacryloylphosphate.

The compounded ratio of the thermosetting resin is not especially limited as long as it is at a level where the die bond films 3 and 3′ exhibit a function of a thermosetting type die bond film when they are heated under a prescribed condition. However, it is preferably in a range of 5 to 60% by weight, and more preferably in a range of 10 to 50% by weight.

The glass transition temperature (Tg) of the die bond films 3 and 3′ before thermal curing is preferably 25 to 60° C., more preferably 25 to 55° C., and further preferably 25 to 50° C. By making the glass transition temperature before thermal curing be 25 to 60° C., a wafer can be laminated well. The glass transition temperature can be measured according to the method described in the Examples.

The glass transition temperature of the die bond films 3 and 3′ before thermal curing can be made 25 to 60° C. by incorporating one or more resins having a melting point of 50° C. or more into at least one of the epoxy resin and the phenol resin. Examples of the epoxy resin having a melting point of 50° C. or more include AER-8039 (manufactured by Asahi Kasei Epoxy, melting point 78° C.), BREN-105 (manufactured by Nippon Kayaku Co., Ltd., melting point 64° C.), BREN-S (manufactured by Nippon Kayaku Co., Ltd., melting point 83° C.), CER-3000L (manufactured by Nippon Kayaku Co., Ltd., melting point 90° C.), EHPE-3150 (manufactured by Daicel Chemical Industries, Ltd., melting point 80° C.), EPPN-501HY (manufactured by Nippon Kayaku Co., Ltd., melting point 60° C.), ESN-165M (manufactured by Nippon Steel Chemical Co., Ltd., melting point 76° C.), ESN-175L (manufactured by Nippon Steel Chemical Co., Ltd., melting point 90° C.), ESN-175S (manufactured by Nippon Steel Chemical Co., Ltd., melting point 67° C.), ESN-355 (manufactured by Nippon Steel Chemical Co., Ltd., melting point 55° C.), ESN-375 (manufactured by Nippon Steel Chemical Co., Ltd., melting point 75° C.), ESPD-295 (manufactured by Sumitomo Chemical Co., Ltd., melting point 69° C.), EXA-7335 (manufactured by DIC Corporation, melting point 99° C.), EXA-7337 (manufactured by DIC Corporation, melting point 70° C.), HP-7200H (manufactured by DIC Corporation, melting point 82° C.), TEPIC-SS (manufactured by Nissan Chemical Industries, Ltd., melting point 108° C.), YDC-1312 (manufactured by Tohto Kasei Co., Ltd., melting point 141° C.), YDC-1500 (manufactured by Tohto Kasei Co., Ltd., melting point 101° C.), YL-6121HN (manufactured by Japan Epoxy Resin Co., Ltd., melting point 130° C.), YSLV-120TE (manufactured by Tohto Kasei Co., Ltd., melting point 113° C.), YSLV-80XY (manufactured by Tohto Kasei Co., Ltd., melting point 80° C.), YX-4000H (manufactured by Japan Epoxy Resin Co., Ltd., melting point 105° C.), YX-4000K (manufactured by Japan Epoxy Resin Co., Ltd., melting point 107° C.), ZX-650 (manufactured by Tohto Kasei Co., Ltd., melting point 85° C.), Epicoat 1001 (manufactured by Japan Epoxy Resin Co., Ltd., melting point 64° C.), Epicoat 1002 (manufactured by Japan Epoxy Resin Co., Ltd., melting point 78° C.), Epicoat 1003 (manufactured by Japan Epoxy Resin Co., Ltd., melting point 89° C.), Epicoat 1004 (manufactured by Japan Epoxy Resin Co., Ltd., melting point 97° C.), and Epicoat 1006FS (manufactured by Japan Epoxy Resin Co., Ltd., melting point 112° C.). Among these, AER-8039 (manufactured by Asahi Kasei Epoxy, melting point 78° C.), BREN-105 (manufactured by Nippon Kayaku Co., Ltd., melting point 64° C.), BREN-S (manufactured by Nippon Kayaku Co., Ltd., melting point 83° C.), CER-3000L (manufactured by Nippon Kayaku Co., Ltd., melting point 90° C.), EHPE-3150 (manufactured by Daicel Chemical Industries, Ltd., melting point 80° C.), EPPN-501HY (manufactured by Nippon Kayaku Co., Ltd., melting point 60° C.), ESN-165M (manufactured by Nippon Steel Chemical Co., Ltd., melting point 76° C.), ESN-175L (manufactured by Nippon Steel Chemical Co., Ltd., melting point 90° C.), ESN-175S (manufactured by Nippon Steel Chemical Co., Ltd., melting point 67° C.), ESN-355 (manufactured by Nippon Steel Chemical Co., Ltd., melting point 55° C.), ESN-375 (manufactured by Nippon Steel Chemical Co., Ltd., melting point 75° C.), ESPD-295 (manufactured by Sumitomo Chemical Co., Ltd., melting point 69° C.), EXA-7335 (manufactured by DIC Corporation, melting point 99° C.), EXA-7337 (manufactured by DIC Corporation, melting point 70° C.), HP-7200H (manufactured by DIC Corporation, melting point 82° C.), YSLV-80XY (manufactured by Tohto Kasei Co., Ltd., melting point 80° C.), ZX-650 (manufactured by Tohto Kasei Co., Ltd., melting point 85° C.), Epicoat 1001 (manufactured by Japan Epoxy Resin Co., Ltd., melting point 64° C.), Epicoat 1002 (manufactured by Japan Epoxy Resin Co., Ltd., melting point 78° C.), Epicoat 1003 (manufactured by Japan Epoxy Resin Co., Ltd., melting point 89° C.), and Epicoat 1004 (manufactured by Japan Epoxy Resin Co., Ltd., melting point 97° C.) are preferable. Because the melting point of these epoxy resins is not too high (less than 100° C.), the wafer lamination property when the resins are used for the die bond film is good. Examples of the phenol resin having a melting point of 50° C. or more include DL-65 (manufactured by Meiwa Plastic Industries, Ltd., melting point 65° C.), DL-92 (manufactured by Meiwa Plastic Industries, Ltd., melting point 92° C.), DPP-L (manufactured by Nippon Oil Corporation, melting point 100° C.), GS-180 (manufactured by Gunei Chemical Industry Co., Ltd., melting point 83° C.), GS-200 (manufactured by Gunei Chemical Industry Co., Ltd., melting point 100° C.), H-1 (manufactured by Meiwa Plastic Industries, Ltd., melting point 79° C.), H-4 (manufactured by Meiwa Plastic Industries, Ltd., melting point 71° C.), HE-100C-15 (manufactured by Sumitomo Chemical Co., Ltd., melting point 73° C.), HE-510-05 (manufactured by Sumitomo Chemical Co., Ltd., melting point 75° C.), HF-1 (manufactured by Meiwa Plastic Industries, Ltd., melting point 84° C.), HF-3 (manufactured by Meiwa Plastic Industries, Ltd., melting point 96° C.), MEH-7500 (manufactured by Meiwa Plastic Industries, Ltd., melting point 111° C.), MEH-7500-35 (manufactured by Meiwa Plastic Industries, Ltd., melting point 83° C.), MEH-7800-3L (manufactured by Meiwa Plastic Industries, Ltd., melting point 72° C.), MEH-7851 (manufactured by Meiwa Plastic Industries, Ltd., melting point 78° C.), MEH-7851-3H (manufactured by Meiwa Plastic Industries, Ltd., melting point 105° C.), MEH-7851-4H (manufactured by Meiwa Plastic Industries, Ltd., melting point 130° C.), MEH-78515 (manufactured by Meiwa Plastic Industries, Ltd., melting point 73° C.), P-1000 (manufactured by Arakawa Chemical Industries, Ltd., melting point 63° C.), P-180 (manufactured by Arakawa Chemical Industries, Ltd., melting point 83° C.), P-200 (manufactured by Arakawa Chemical Industries, Ltd., melting point 100° C.), VR-8210 (manufactured by Mitsui Chemicals, Inc., melting point 60° C.), XLC-3L (manufactured by Mitsui Chemicals, Inc., melting point 70° C.), XLC-4L (manufactured by Mitsui Chemicals, Inc., melting point 62° C.), and XLC-LL (manufactured by Mitsui Chemicals, Inc., melting point 75° C.). Among these, DL-65 (manufactured by Meiwa Plastic Industries, Ltd., melting point 65° C.), DL-92 (manufactured by Meiwa Plastic Industries, Ltd., melting point 92° C.), GS-180 (manufactured by Gunei Chemical Industry Co., Ltd., melting point 83° C.), H-1 (manufactured by Meiwa Plastic Industries, Ltd., melting point 79° C.), H-4 (manufactured by Meiwa Plastic Industries, Ltd., melting point 71° C.), HE-100C-15 (manufactured by Sumitomo Chemical Co., Ltd., melting point 73° C.), HE-510-05 (manufactured by Sumitomo Chemical Co., Ltd., melting point 75° C.), HF-1 (manufactured by Meiwa Plastic Industries, Ltd., melting point 84° C.), HF-3 (manufactured by Meiwa Plastic Industries, Ltd., melting point 96° C.), MEH-7500-35 (manufactured by Meiwa Plastic Industries, Ltd., melting point 83° C.), MEH-7800-3L (manufactured by Meiwa Plastic Industries, Ltd., melting point 72° C.), MEH-7851 (manufactured by Meiwa Plastic Industries, Ltd., melting point 78° C.), MEH-78515 (manufactured by Meiwa Plastic Industries, Ltd., melting point 73° C.), P-1000 (manufactured by Arakawa Chemical Industries, Ltd., melting point 63° C.), P-180 (manufactured by Arakawa Chemical Industries, Ltd., melting point 83° C.), VR-8210 (manufactured by Mitsui Chemicals, Inc., melting point 60° C.), XLC-3L (manufactured by Mitsui Chemicals, Inc., melting point 70° C.), XLC-4L (manufactured by Mitsui Chemicals, Inc., melting point 62° C.), and XLC-LL (manufactured by Mitsui Chemicals, Inc., melting point 75° C.) are preferable. Because the melting point of these phenol resins is not too high (less than 100° C.), the wafer lamination property when the resins are used for the die bond film is good.

The die bond films 3 and 3′ contain an epoxy resin, a phenol resin, and an acrylic resin. Defining the total weight of the epoxy resin and the phenol resin as X and the weight of the acrylic resin as Y, X/(X+Y) is preferably 0.3 or more and less than 0.9, more preferably 0.35 or more and less than 0.85, and further preferably 0.4 or more and less than 0.8. As the content of the epoxy resin and the phenol resin increases, the die bond film can be easily broken and the tackiness to the semiconductor wafer 4 decreases. Further, as the content of the acrylic resin increases, workability becomes good because it becomes difficult for the die bond films 3 and 3′ to crack upon pasting or handling and it becomes difficult for the die bond films 3 and 3′ to break. By making X/(X+Y) be 0.3 or more, the die bond films 3 and 3′ and the semiconductor wafer 4 can be broken together at the same time more easily compared to the case where a semiconductor element 5 is obtained from the semiconductor wafer 4 by stealth dicing. By making X/(X+Y) be less than 0.9, the workability can be made good.

In order to crosslink the die bond film 3, 3′ of the present invention to some extent in advance, it is preferable to add, as a crosslinking agent, a polyfunctional compound which reacts with functional groups of molecular chain terminals of the above-mentioned polymer to the materials used when the sheet 12 is produced. In this way, the adhesive property of the sheet at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

A filler can be appropriately mixed into the die bond films 3, 3′ according to their use. By mixing the filler, electroconductivity can be given, thermal conductivity can be improved, and the elastic modulus can be adjusted. Examples of the filler include an inorganic filler and an organic filler. However, an inorganic filler is preferable from the viewpoint of improving handling property, improving thermal conductivity, adjusting melt viscosity, and giving thixotropy. The inorganic filler is not especially limited, and examples thereof include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, crystalline silica, and amorphous silica. These can be used alone or two types or more can be used together. From the viewpoint of improving thermal conductivity, aluminum oxide, aluminum nitride, boron nitride, crystalline silica, and amorphous silica are preferable. From the viewpoint of obtaining a good balance among the above-described characteristics, crystalline silica and amorphous silica are preferable. Further, an electroconductive substance (electroconductive filler) may be used as the inorganic filler for the purpose of giving electroconductivity and improving the thermal conductivity. Examples of the electroconductive filler include spherical-shaped, needle-shaped, or flake-shaped metal powders of silver, aluminum, gold, copper, nickel, and electroconductive alloys, metal oxides such as alumina, amorphous carbon black, and graphite.

The average particle size of the filler is preferably 0.005 to 10 μm, and more preferably 0.005 to 1 μm. With the average particle size of the filler being 0.005 μm or more, the wettability and the tackiness to the adherend can be improved. With the particle size being 10 μm or less, the effect of the filler added to give the above-described characteristics can be made sufficient, and heat resistance can be secured. The value of the average particle size of the filler is obtained with a luminous intensity type particle size distribution meter (manufactured by HORIBA, Ltd., device name: LA-910), for example.

When the total weight of the epoxy resin, the phenol resin, and the acrylic resin is regarded as A and the weight of the filler is regarded as B, the value of A/(A+B) is preferably 0.1 or more to 0.7 or less, more preferably 0.1 or more to 0.65 or less, and further preferably 0.1 of more to 0.6 or less. With this value being 0.7 or less, the tensile storage modulus is prevented from becoming large, and wettability and tackiness to the adherend can be improved. With this value being 0.1 or more, the die bond film can be suitably broken with a tensile force.

Moreover, other additives besides the filler can be appropriately mixed into the die bond films 3 and 3′ as necessary. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The thickness of the die bond films 3 and 3′ (the total thickness in the case of a laminated body) is not especially limited. However, it can be selected from a range of 1 to 200 μm, for example. It is preferably selected from a range of 5 to 100 μm, and more preferably 10 to 80 μm.

The die bond films 3, 3′ of the dicing die bond films 10, 11 are preferably protected by a separator (not shown). The separator has a function as a protecting material that protects the die bond films 3, 3′ until they are practically used. Further, the separator can be used as a supporting base material when transferring the die bond films 3, 3′ to the pressure-sensitive adhesive layer 2. The separator is peeled when pasting a workpiece onto the die bond films 3, 3′ of the dicing die bond film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The dicing die bond films 10, 11 according to the present embodiment are produced, for example, by the following procedure. First, the base material 1 can be formed by a conventionally known film-forming method. The film-forming method includes, for example, a calendar film-forming method, a casting method in an organic solvent, an inflation extrusion method in a closed system, a T-die extrusion method, a co-extrusion method, and a dry lamination method.

Next, a pressure-sensitive adhesive composition solution is applied on the base material 1 to form a coated film and the coated film is dried under predetermined conditions (optionally crosslinked with heating) to form the pressure-sensitive adhesive layer 2. Examples of the application method include, but are not limited to, roll coating, screen coating and gravure coating methods. Drying is conducted under the drying conditions, for example, the drying temperature within a range from 80 to 150° C. and the drying time within a range from 0.5 to 5 minutes. The pressure-sensitive adhesive layer 2 may also be formed by applying a pressure-sensitive adhesive composition on a separator to form a coated film and drying the coated film under the drying conditions. Then, the pressure-sensitive adhesive layer 2 is laminated on the base material 1 together with the separator. Thus, the dicing film 11 is produced.

The die bond films 3, 3′ are produced, for example, by the following procedure.

First, an adhesive composition solution as a material for forming the die bond films 3, 3′ is produced. As described above, the adhesive composition solution is blended with the adhesive composition, a filler, and various additives.

Next, the adhesive composition solution is applied on a substrate separator to form a coated film having a predetermined thickness and the coated film is dried under predetermined conditions to form an adhesive layer. Examples of the application method include, but are not limited to, roll coating, screen coating and gravure coating methods. Drying is conducted under the drying conditions, for example, the drying temperature within a range from 70 to 160° C. and the drying time within a range from 1 to 5 minutes. An adhesive layer may also be formed by applying a pressure-sensitive adhesive composition solution on a separator to form a coated film and drying the coated film under the drying conditions. On the substrate separator, the adhesive layer is layered together with a separator.

Subsequently, each separator is peeled from the dicing film 11 and the adhesive layer and both are laminated to each other so that the adhesive layer and the pressure-sensitive adhesive layer serve as a laminating surface. Lamination is conducted, for example, by contact bonding. At this time, the lamination temperature is not particularly limited and is, for example, preferably from 30 to 50° C., and more preferably from 35 to 45° C. The linear pressure is not particularly limited and is, for example, from 0.1 to 20 kgf/cm, and more preferably from 1 to 10 kgf/cm. Then, the substrate separator on the adhesive layer is peeled to obtain the dicing die bond film according to the present embodiment.

### (Method of Manufacturing Semiconductor Device)

Next, a method of manufacturing a semiconductor device using the dicing die bond film 12 is explained by referring to FIGS. 3 to 8. FIGS. 3 to 6 are schematic sectional views for explaining one method of manufacturing a semiconductor device according to the present embodiment. First, a reforming region is formed on the predetermined dividing lines 4L by irradiating the predetermined dividing lines 4L of the semiconductor wafer 4 with a laser beam. The present method is a method of forming a reformed region inside the semiconductor wafer by ablation caused by multi-photon absorption by focusing condensing points on the inside of the semiconductor wafer and irradiating the semiconductor water with a laser beam along the lattice-shaped scheduled dividing lines. The irradiation conditions of the laser beam are appropriately adjusted within the following ranges.

### <Laser Beam Irradiation Conditions>

### (A) Laser Beam

Laser Beam Source Semiconductor laser excitation Nd:YAG laser Wavelength 1064 nm

Sectional Area of Laser Spot 3.14×10⁻⁸ cm²
Laser Oscillation Form Q switch pulse
Repetition Frequency 100 kHz or less
Pulse Width μs or less
Output 1 mJ or less

### Quality of Laser Beam TEM00

Polarization Characteristic Linear polarization

### (B) Beam Collecting Lens

Magnification 100 times or less

### NA 0.55

Transmittance to Laser Beam Wavelength 100% or less

### (C) Movement Speed of the Stage on Which Semiconductor

Substrate is Loaded 280 mm/sec or less A detailed explanation of the method of forming a reformed region on the scheduled dividing lines 4L by irradiating the semiconductor wafer with a laser beam is omitted because it is specifically described in Japanese Patent No. 3408805 and Japanese Patent Application Laid-Open No. 2003-338567.

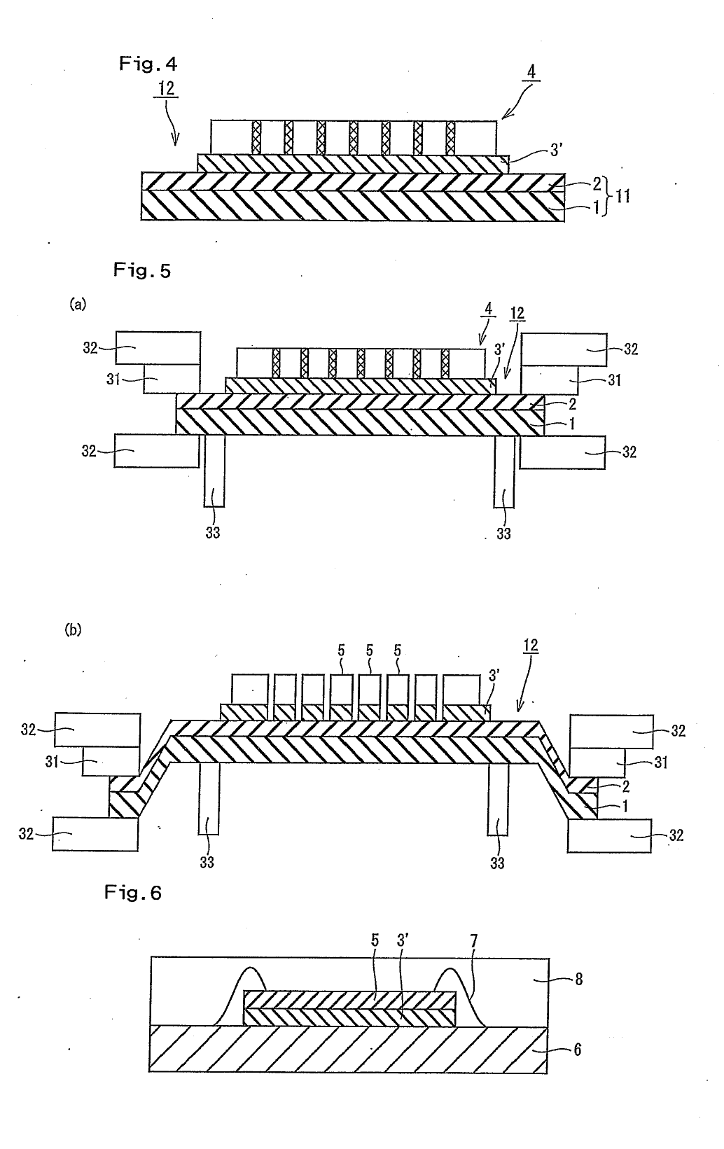

Next, as shown in FIG. 4, the semiconductor wafer 4 after the formation of the reforming region is press bonded to the die bond film 3′ and fixed by adhering and holding the wafer 4 (a mounting step). This step is performed while pressing the wafer with a pressing means such as a press bonding roll. The bonding temperature during mounting is not especially limited, however, it is preferably in the range of 40 to 80° C. This is because warping of the semiconductor wafer 4 can be effectively prevented and the influence of expansion and contraction of the dicing die bond film can be reduced.

Next, the semiconductor chip 5 is formed by breaking the semiconductor wafer 4 and the die bond film 3′ at the predetermined dividing lines 4L by applying tensile force to the dicing die bond film 12 (a chip forming step). In this step, a wafer expander on the market can be used, for example. Specifically, a dicing ring 31 is bonded onto the peripheral part of a pressure-sensitive adhesive layer 2 of the dicing die bond film 12 on which the semiconductor wafer 4 is bonded, and then it is fixed onto a wafer expander 32 as shown in FIG. 5A. Next, a tensile force is applied to the dicing die bond film 12 by raising a push-up part 33 as shown in FIG. 5B.

The chip forming step is performed under a condition of 0 to 25° C., preferably 10 to 25° C., and more preferably 15 to 25° C. Because the chip forming step is performed under a condition of 0 to 25° C. and the die bond film 3′ does not have to be put into a low temperature state, the chip forming step can be performed right after the mounting step. As a result, the manufacturing efficiency can be improved. Because the chip forming step is performed under a condition of 0 to 25° C. that is around room temperature, the set temperature hardly deviates from 0 to 25° C. due to the ability of the apparatus and the external environment. As a result, the yield can be improved.

The expansion speed (the speed at which the push-up portion rises) in the chip forming step is 100 to 400 mm/sec, preferably 100 to 350 mm/sec, and more preferably 100 to 300 mm/sec. By making the expansion speed be 100 mm/sec or more, the semiconductor wafer 4 and the die bond film 3′ can be substantially simultaneously broken easily. By making the expansion speed be 400 mm/sec or less, the dicing film 11 can be prevented from breaking.

The expansion amount in the chip forming step is 6 to 12%. The expansion amount may be appropriately adjusted in the above-described numerical range according to the chip size that is formed. The expansion amount in the present invention is the value (%) of the surface area that is increased by expansion from the surface area of the dicing film before expansion (regarded as 100%). By making the expansion amount be 6% or more, the semiconductor wafer 4 and the die bond film 3 can be easily broken. By making the expansion amount be 12% or less, the dicing film 11 can be prevented from breaking.

As described above, cracks can be generated in the thickness direction of the semiconductor wafer 4 with the reformed region of the semiconductor wafer 4 as a starting point, the die bond film 3′ that is closely attached to the semiconductor wafer 4 can be broken by applying a tensile force to the dicing die bond film 12, and the semiconductor chip 5 with the die bond film 3′ can be obtained.

Next, pickup of the semiconductor chip 5 is performed to peel off the semiconductor chip 5 that is adhered and fixed onto the dicing die bond film 12 (the pickup step). The method of picking up is not particularly limited, and conventionally known various methods can be adopted. Examples include a method of pushing up the individual semiconductor chip 5 from the dicing die-bonding 10 side with a needle and picking up the pushed semiconductor chip 5 with a picking-up apparatus.

Here, the picking up is performed after radiating the pressure-sensitive adhesive layer 2 with ultraviolet rays because the pressure-sensitive adhesive layer 2 is an ultraviolet curable type pressure-sensitive adhesive layer. Accordingly, the adhesive strength of the pressure-sensitive adhesive layer 2 to the die bond film 3a decreases, and the peeling of the semiconductor chip 5 becomes easy. As a result, picking up becomes possible without damaging the semiconductor chip 5. The condition such as irradiation intensity and irradiation time when irradiating an ultraviolet ray is not particularly limited, and it may be appropriately set depending on necessity. Further, the light source as described above can be used as a light source used in the ultraviolet irradiation.

Next, the semiconductor chip 5 that is picked up is die-bonded to the adherend 6 through the die bond film 3′ as shown in FIG. 6 (the temporary fixing step). Examples of the adherend 6 include such as a lead frame, a TAB film, a substrate, and a semiconductor chip separately produced. The adherend 6 may be a deformable adherend that are easily deformed, or may be a non-deformable adherend (a semiconductor wafer, etc.) that is difficult to deform, for example.

A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

The shear adhering strength to the adherend 6 at 25° C. during the temporary fixing of the die bond film 3′ is preferably 0.2 MPa or more, and more preferably 0.2 to 10 MPa. When the shear adhering strength of the die bond film 3 is at least 0.2 MPa, shear deformation rarely occurs at the adhering surface between the die bond film 3 and the semiconductor chip 5 or the adherend 6 during the wire bonding step due to ultrasonic vibration and heating in this step. That is, the semiconductor element rarely moves due to the ultrasonic vibration during the wire bonding, and with this, the success rate of the wire bonding can be prevented from decreasing. The shear adhering strength to the adherend 6 at 175° C. during the temporary fixing of the die bond film 3′ is preferably 0.01 MPa or more, and more preferably 0.01 to 5 MPa.

Next, wire bonding is performed to electrically connect a tip of a terminal part (inner lead) of the adherend 6 and an electrode pad (not shown) on the semiconductor chip 5 with a bonding wire 7 (the wire bonding step). The bonding wires 7 may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range. The present step can be conducted without thermal setting of the die bond film 3a. In the process of the step, the semiconductor chip 5 and the adherend 6 are not fixed to each other by the die bond film 3a.

Next, the semiconductor chip 5 is sealed with the sealing resin 8 (the sealing step). The present step is performed by molding the sealing resin with a mold or die. The sealing resin 8 may be, for example, an epoxy resin. The heating for the resin-sealing is performed usually at 175° C. for 60 to 90 seconds. In the this invention, however, the heating is not limited to this, and may be performed, for example at 165 to 185° C. for several minutes. In such a way, the sealing resin is cured and further the semiconductor chip 5 and the adhernd 6 are set to each other through the adhesive sheet 3a. In short, even if the below mentioned post-curing step, which will be detailed later, is not performed in this invention, the sticking/fixing based on the adhesive sheet 3a can be attained in the present step so that the number of the producing steps can be reduced and the term for producing the semiconductor device can be shortened.

In the post-curing step, the sealing resin 8, which is not sufficiently cured in the sealing step, is completely cured. Even if the die bond film 3a is not completely cured in the step of sealing, the die bond film 3a and sealing resin 8 can be completely cured in the present step. The heating temperature in the present step is varied dependently on the kind of the sealing resin, and is, for example, in the range of 165 to 185° C. The heating time is from about 0.5 to 8 hours.

The case of temporarily fixing the semiconductor chip 5 with the die bond film 3′ to the adherend 6 and then performing the wire bonding step without completely thermally curing the die bond film 3′ is explained in the above-described embodiment. However, a normal die bonding step of temporarily fixing the semiconductor chip 5 with the die bond film 3′ to the adherend 6, thermally curing the die bond film 3′, and then performing the wire bonding step may be performed in the present invention. In this case, the die bond film 3′ after the thermal setting preferably has a shear adhering strength at 175° C. of 0.01 MPa or more, and more preferably 0.01 to 5 MPa. With the shear adhering strength at 175° C. after the thermal setting being 0.01 MPa or more, the shear deformation at the adhering surface between the die bond film 3′ and the semiconductor chip 5 or the adherend 6 due to ultrasonic vibration and heating during the wire bonding step can be prevented from occurring.

The dicing die bond film of the present invention can be suitably used when laminating a plurality of semiconductor chips to carry out three-dimensional mounting. At this time, a die bond film and a spacer may be laminated between the semiconductor chips, or only a die bond film may be laminated between semiconductor chips without laminating a spacer. The mode of mounting can be appropriately changed according to the manufacturing condition and the use.

Next, a method of manufacturing a semiconductor device is explained below, in which the steps of forming grooves on a surface of a semiconductor wafer and performing backside grinding are adopted.

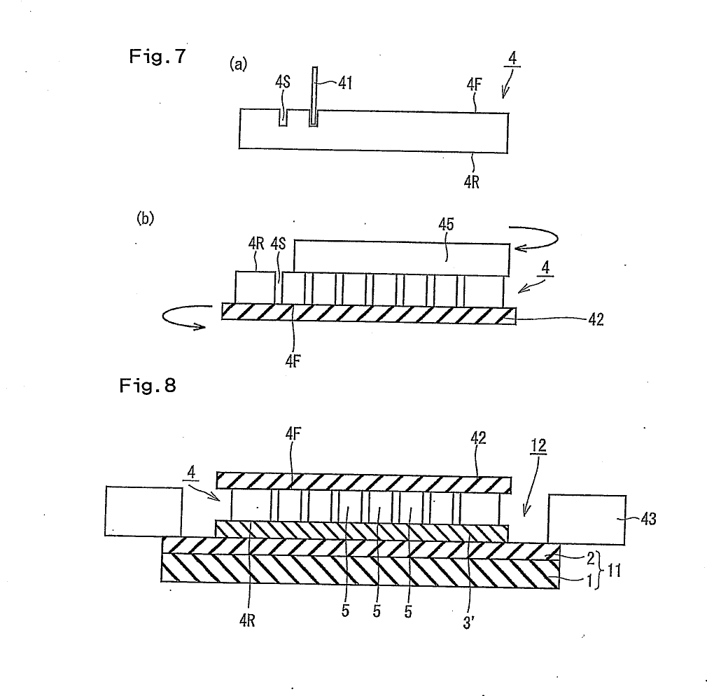

FIGS. 7 and 8 are schematic sectional views for explaining another method of manufacturing a semiconductor device according to the present embodiment. First, a groove 4S that does not reach backside 4R is formed on a surface 4F of the semiconductor wafer 4 with a rotary blade 41 as shown in FIG. 7A. The semiconductor wafer 4 is supported by a supporting base that is not shown during the formation of the groove 4S. The depth of the groove 4S can be appropriately set depending on the thickness of the semiconductor wafer 4 and the expansion condition. Next, the semiconductor wafer 4 is made to be supported by a protecting base 42 so that the surface 4F is brought into contact with itself as shown in FIG. 7B. Then, the groove 4S is exposed from the backside 4R by performing backside grinding with a grinding wheel 45. A conventionally known bonding apparatus can be used to bond the protecting base 42 onto the semiconductor wafer, and a conventionally known grinding apparatus can be used for the backside grinding.

Next, as shown in FIG. 8, the semiconductor wafer 4 with grooves 4S exposed is press bonded to the dicing die bond film 12 and fixed by adhering and holding the wafer 4 (a temporary fixing step). After that, the protective base 42 is peeled off, and tensile force is applied to the dicing die bond film 12 by a wafer expansion apparatus 32. With this operation, the die bond film 3′ is broken and the semiconductor chip 5 is formed (a chip forming step). The temperature, the expansion speed, and the expansion amount in the chip forming step are the same as in the case of forming the reforming region on the predetermined dividing lines 4L by irradiation with a laser beam. Explanation of the following processes is omitted because it is the same as the case where the reformed region is formed on the scheduled dividing lines 4L by irradiating the semiconductor wafer with a laser beam.

Below, preferred examples of the present invention are explained in detail. However, materials, addition amounts, and the like described in these examples are not intended to limit the scope of the present invention, and are only examples for explanation as long as there is no description of limitation in particular.

### Example 1

An adhesive composition solution having a concentration of 23.6% by weight was obtained by dissolving the following (a) to (d) in methyl ethyl ketone.

(a) 280 parts by weight of an epoxy resin (Epicoat 1004 manufactured by Japan Epoxy Resin Co., Ltd., melting point: 97° C.)

(b) 306 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 237 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film A.

### Example 2

In Example 2, a die bond film B according to the present example was produced in the same manner as in Example 1 except that the added amount of the epoxy resin of (a) was changed to 270 parts by weight and the added amount of the phenol resin of (b) was changed to 296 parts by weight.

### Example 3

In Example 3, a die bond film C according to the present example was produced in the same manner as in Example 1 except that the added amount of the epoxy resin of (a) was changed to 113 parts by weight and the added amount of the phenol resin of (b) was changed to 121 parts by weight.

### Example 4

In Example 4, a die bond film D according to the present example was produced in the same manner as in Example 1 except that the added amount of the epoxy resin of (a) was changed to 40 parts by weight and the added amount of the phenol resin of (b) was changed to 41 parts by weight.

### Example 5

In Example 5, a die bond film E according to the present example was produced in the same manner as in Example 1 except that the added amount of the epoxy resin of (a) was changed to 14 parts by weight and the added amount of the phenol resin of (b) was changed to 17 parts by weight.

### Comparative Example 1

An adhesive composition solution having a concentration of 23.6% by weight was obtained by dissolving the following (a) to (d) in methyl ethyl ketone.

(a) 173 parts by weight of an epoxy resin (Epicoat 1004 manufactured by Japan Epoxy Resin Co., Ltd., melting point: 97° C.)

(b) 227 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-P3 manufactured by Nagase ChemteX Corporation, glass transition temperature: 15° C.)

(d) 371 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film F.

### Comparative Example 2

In Comparative Example 2, a die bond film G according to the present example was produced in the same manner as in Example 1 except that the added amount of the epoxy resin of (a) was changed to 11 parts by weight and the added amount of the phenol resin of (b) was changed to 13 parts by weight.

### (Elongation Rate at Break)

A rectangular measurement piece 30 mm in length, 25 μm in thickness, and 10 mm in width was cut from each of the die bond films A to G. Next, the elongation rate at break was obtained by stretching the measurement pieces using a tensile tester (TENSILON manufactured by Shimadzu Corporation) under conditions of a tensile speed of 0.5 ram/min and a distance between chucks of 20 mm and using the following formula. The result is shown in Table 1.

Elongation rate at break (%)=(((Length between chucks at break (mm))−20)/20)×100

### (Measurement of the Glass Transition Temperature Before Thermal Curing)

The die bond films A to G were put on top of each other to a thickness of 100 μm under a condition of 40° C., and then it was cut into a rectangular measurement piece of 10 mm in width. Next, the loss tangent (tan δ) at −30 to 280° C. was measured under conditions of a frequency of 10 Hz and a temperature rise rate of 5° C./min using a dynamic viscoelasticity measurement apparatus (RSA III manufactured by Rheometric Scientific FE, Ltd.). The glass transition temperature that was obtained from a peak value of the tan δ from the measurement is shown in Table 1.

### (Measurement of the Tensile Storage Modulus and the Loss Modulus at 10 Hz)

A rectangular measurement piece 30 mm in length, 5 mm in width, and 400 μm in thickness was cut from each of the die bond films A to G. Next, the tensile storage modulus and the loss tangent (tan δ) at −30 to 100° C. were measured under conditions of a distance between chucks of 20 mm, a frequency of 10 Hz, and a temperature rise rate of 5° C./min using a dynamic viscoelasticity measurement apparatus (RSA III manufactured by Rheometric Scientific FE, Ltd.). The tensile storage modulus at −20° C., the tensile storage modulus at 0° C. (a), the tensile storage modulus at 25° C. (b), and the loss modulus at 25° C. at that time are shown in Table 1. The ratio (b/a) is also shown in Table 1.

TABLE 1

| | | Storage | Storage | | Glass | Storage | |
|---|---|---|---|---|---|---|---|
| | Elongation | modulus (a) | modulus (b) | Ratio (b/a) | transition | modulus | Loss modulus |
| | rate at break | (MPa) at 0° C. | (MPa) at 25° C. | of storage | temperature | (MPa) at | (MPa) at 25° C. |
| | (%) | and 10 Hz | and 10 Hz | modulus | (° C.) | −20° C. and 10 Hz | and 10 Hz |
| Example 1 | 45 | 2710 | 2460 | 0.91 | 38 | 2720 | 990 |
| Example 2 | 121 | 2975 | 2240 | 0.75 | 40 | 2980 | 925 |
| Example 3 | 180 | 3300 | 1580 | 0.48 | 41 | 3310 | 588 |
| Example 4 | 172 | 3510 | 811 | 0.23 | 51 | 3530 | 453 |
| Example 5 | 463 | 3980 | 716 | 0.18 | 54 | 3990 | 413 |
| Comparative | 10 | 2830 | 2840 | 1.00 | 79 | 2880 | 845 |
| Example 1 | | | | | | | |
| Comparative | 523 | 5840 | 226 | 0.04 | 21 | 6140 | 122 |
| Example 2 | | | | | | | |

### (Confirmation of Breakage)<

Case in which a step (step 1) was adopted in which a reformed region was formed on the scheduled dividing lines 4L by irradiating the semiconductor wafer with a laser beam>

A reformed region was formed in the interior of the semiconductor wafer by focusing condensing points in the interior of the semiconductor wafer and irradiating the semiconductor wafer with a laser beam at the surface of the semiconductor wafer along the lattice-shaped (10 mm×10 mm) scheduled dividing lines using ML300-Integration manufactured by Tokyo Seimitsu Co., Ltd. as a laser beam machining apparatus. A silicon wafer (thickness: 75 μm, outer diameter: 12 inches) was used as the semiconductor wafer. The irradiation conditions of the laser beam were as follows.

<Laser Beam Irradiation Conditions>

(A) Laser Beam
Laser Beam Source Semiconductor laser excitation Nd:YAG laser
Wavelength 1064 nm
Sectional Area of Laser Spot 3.14 × 10⁻⁸ cm²
Laser Oscillation Form Q switch pulse
Repetition Frequency 100 kHz
Pulse Width 30 ns
Output 20 μJ/pulse
Quality of Laser Beam TEM00 40
Polarization Characteristic Linear polarization
(B) Beam Collecting Lens
Magnification 50 times
NA 0.55
Transmittance to Laser Beam Wavelength 60%
(C) Movement Speed of the Stage on Which Semiconductor
Substrate is Loaded 100 mm/sec

A semiconductor wafer to which a pre treatment by a laser beam had been performed was pasted to each of the die bond films A to G, and then a breaking test was performed. The breaking test was performed at each of the expansion temperatures of 0° C., 10° C., and 25° C. The expansion speed was 400 mm/sec and the expansion amount was 6%. The number of chips for which the chip and the die bond film were broken well at the predetermined dividing lines as a result of the breaking test was counted for 100 chips in the center portion of the semiconductor wafer. However, the measurement was not performed for Comparative Example 1 because the die bond film F did not stick to the semiconductor wafer and workability was poor due to brittleness of the die bond film F. The result is shown in Table 2.

<Case in which a Step (Step 2) was Adopted in which Grooves were Formed on the Surface of the Semiconductor Wafer and then Backside Grinding was Performed>

Lattice-shaped (10 mm×10 mm) cut grooves were formed on the semiconductor wafer (thickness 500 μm) by blade dicing. The depth of the cut grooves was 100 μm.

Next, divided individual semiconductor chips (10 mm×10 mm×75 μm) were obtained by protecting the surface of the semiconductor wafer with a protecting tape and performing backside grinding until the thickness reached 75 μm. This semiconductor chip was bonded onto each of the die bond films A to g, and then the breaking test was performed. The breaking test was performed at each of the expansion temperatures of 0° C., 10° C., and 25° C. The expansion speed was 400 mm/sec and the expansion amount was 6%. The number of chips for which the die bond film was broken well as a result of the breaking test was counted for 100 chips in the center portion of the semiconductor wafer. However, the measurement was not performed for Comparative Example 1 because the die bond film F did not stick to the semiconductor wafer and workability was poor due to brittleness of the die bond film F. The result is shown in Table 2.

TABLE 2

| | Breaking property | | | | | |
|---|---|---|---|---|---|---|
| | Step 1 | | | Step 2 | | |
| | 0° C. | 10° C. | 25° C. | 0° C. | 10° C. | 25° C. |
| Example 1 | 100 | 100 | 100 | 100 | 100 | 100 |
| Example 2 | 100 | 100 | 100 | 100 | 100 | 100 |
| Example 3 | 100 | 100 | 100 | 100 | 100 | 100 |
| Example 4 | 100 | 100 | 100 | 100 | 100 | 100 |
| Example 5 | 100 | 100 | 100 | 100 | 100 | 100 |
| Comparative | — | — | — | — | — | — |
| Example 1 | | | | | | |
| Comparative | 95 | 48 | 10 | 87 | 39 | 0 |
| Example 2 | | | | | | |

### (Result)

As can be understood from the result in Table 2, it was confirmed that the chip and the die bond film can be broken well at the predetermined dividing lines in step 1 by using the die bond films A to G having the elongation rate at break at 25° C. before thermal curing larger than 40% and 500% or less. Further, it was confirmed that the die bond film can be broken well in step 2.

### Example 6

An adhesive composition solution having a concentration of 23.6% by weight was obtained by dissolving the following (a) to (d) in methyl ethyl ketone.

(a) 54 parts by weight of an epoxy resin (Epicoat 1004 manufactured by Japan Epoxy Resin Co., Ltd., melting point: 97° C.)

(b) 71 parts by weight of a phenol resin (Milex XLC-4L manufactured by Mitsui Chemicals, Inc., melting point: 62° C.) (c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 277 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film J.

### Example 7

An adhesive composition solution having a concentration of 23.6% by weight was obtained by dissolving the following (a) to (d) in methyl ethyl ketone.

(a) 114 parts by weight of an epoxy resin (Epicoat 1004 manufactured by Japan Epoxy Resin Co., Ltd., melting point: 97° C.)

(b) 121 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 237 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film K.

### Example 8

An adhesive composition solution having a concentration of 23.6% by weight was obtained by dissolving the following (a) to (d) in methyl ethyl ketone.

(a) 271 parts by weight of an epoxy resin (Epicoat 1004 manufactured by Japan Epoxy Resin Co., Ltd., melting point: 97° C.)

(b) 296 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 237 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film L.

### Example 9

An adhesive composition solution having a concentration of 23.6% by weight was obtained by dissolving the following (a) to (d) in methyl ethyl ketone.

(a) 44 parts by weight of an epoxy resin (Epicoat 1004 manufactured by Japan Epoxy Resin Co., Ltd., melting point: 97° C.)

(b) 56 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 246 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film M.

### Comparative Example 3

An adhesive composition solution having a concentration of 23.6% by weight was obtained by dissolving the following (a) to (d) in methyl ethyl ketone.

(a) 10 parts by weight of an epoxy resin (Epicoat 1004 manufactured by Japan Epoxy Resin Co., Ltd., melting point: 97° C.)

(b) 14 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 111 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film N.

### Comparative Example 4

An adhesive composition solution having a concentration of 23.6% by weight was obtained by dissolving the following (a) to (d) in methyl ethyl ketone.

(a) 32 parts by weight of an epoxy resin (Epicoat 827 manufactured by Japan Epoxy Resin Co., Ltd., melting point: 97° C.)

(b) 37 parts by weight of a phenol resin (Milex XLC-4L manufactured by Mitsui Chemicals, Inc., melting point: 62° C.)

(c) 100 parts by weight of an acrylic acid ester-based polymer having ethyl acrylate-methyl methacrylate as a main component (SG-708-6 manufactured by Nagase ChemteX Corporation, glass transition temperature: 6° C.)

(d) 237 parts by weight of spherical silica (SO-25R manufactured by Admatechs Co., Ltd.)

This adhesive composition solution was applied on a release-treated film (peel liner) composed of a 50 μm thick polyethylene terephthalate film subjected to a silicone release treatment and then dried at 130° C. for 2 minutes to produce a 25 μm thick die bond film O.

### (Elongation Rate at Break)

The elongation rate at break was obtained for the die bond films J to O by the same method as in Examples 1 to 5 and Comparative Examples 1 and 2. The result is shown in Table 3.

### (Measurement of the Tensile Storage Modulus at 900 Hz)

A rectangular measurement piece 30 mm in length, 5 mm in width, and 400 win thickness was cut from each of the die bond films J to O. Next, the tensile storage modulus at −30 to 100° C. was measured under conditions of a distance between chucks of 20 mm, a frequency of 900 Hz, and a temperature rise rate of 5° C./min using a solid viscoelasticity measurement apparatus (DVE-V4 manufactured by Rheology). The tensile storage modulus

(c) at 0° C. and the tensile storage modulus (d) at 25° C. at that time are shown in Table 3. The ratio (c/d) is also shown in Table 3.

### (Confirmation of Breakage)

The breaking test was performed on the die bond films J to O by the same method as in Examples 1 to 5 and Comparative Examples 1 and 2. The result is shown in Table 3.

TABLE 3

| | | Storage | Storage | | | | | | | |
|---|---|---|---|---|---|---|---|---|---|---|
| | Elongation | modulus (c) | modulus (d) | Ratio (c/d) | Breaking property | | | | | |
| | rate at | (MPa) at 0° C. | (MPa) at 25° C. | of storage | Step 1 | | | Step 2 | | |
| | break (%) | and 900 Hz | and 900 Hz | modulus | 0° C. | 10° C. | 25° C. | 0° C. | 10° C. | 25° C. |
| Example 6 | 203 | 5820 | 4210 | 0.72 | 100 | 100 | 100 | 100 | 100 | 100 |
| Example 7 | 193 | 6630 | 4950 | 0.75 | 100 | 100 | 100 | 100 | 100 | 100 |
| Example 8 | 188 | 5290 | 4330 | 0.82 | 100 | 100 | 100 | 100 | 100 | 100 |
| Example 9 | 450 | 6350 | 5380 | 0.85 | 100 | 100 | 100 | 100 | 100 | 100 |
| Comparative | 625 | 4980 | 3210 | 0.64 | 91 | 42 | 3 | 84 | 33 | 0 |
| Example 3 | | | | | | | | | | |
| Comparative | 526 | 6900 | 2890 | 0.42 | 95 | 48 | 10 | 87 | 39 | 0 |
| Example 4 | | | | | | | | | | |

### (Result)

As can be understood from the result in Table 3, it was confirmed that the chip and the die bond film can be broken well at the predetermined dividing lines in step 1 by using the die bond films J to O having the elongation rate at break at 25° C. before thermal curing larger than 40% and 500% or less. Further, it was confirmed that the die bond film can be broken well in step 2.

1. A thermosetting type die bond film used for a method of obtaining a semiconductor element from a semiconductor wafer by forming a reforming region by irradiating the semiconductor wafer with a laser beam and then breaking the semiconductor wafer in the reforming region or a method of obtaining a semiconductor element from a semiconductor wafer by forming grooves that do not reach the backside of the semiconductor wafer on a surface thereof and then exposing the grooves from the backside by grinding the backside of the semiconductor wafer, wherein the elongation rate at break at 25° C. before thermal curing is larger than 40% and 500% or less.

2. The thermosetting type die bond film according to claim 1, wherein the ratio (b/a) of a tensile storage modulus (b) at 25° C. and 10 Hz to a tensile storage modulus (a) at 0° C. and 10 Hz obtained from a dynamic viscoelasticity measurement before thermal curing is 0.15 to 1.

3. The thermosetting type die bond film according to claim 2, wherein the tensile storage modulus at 0° C. and 10 Hz obtained from a dynamic viscoelasticity measurement before thermal curing is 2500 to 5000 MPa.

4. The thermosetting type die bond film according to claim 2, wherein the tensile storage modulus at 25° C. and 10 Hz obtained from a dynamic viscoelasticity measurement before thermal curing is 700 to 2500 MPa.

5. The thermosetting type die bond film according to claim 2, wherein the glass transition temperature before thermal curing is 25 to 60° C.

6. The thermosetting type die bond film according to claim 1, wherein the tensile storage modulus at −20° C. and 10 Hz obtained from a dynamic viscoelasticity measurement before thermal curing is 2000 to 4000 MPa.

7. The thermosetting type die bond film according to claim 1, wherein the loss modulus at 25° C. and 10 Hz obtained from a dynamic viscoelasticity measurement before thermal curing is 400 to 1000 MPa.

8. The thermosetting type die bond film according to claim 2, wherein the film comprises an epoxy resin, a phenol resin, and an acrylic resin, and defining the total weight of the epoxy resin and the phenol resin as X and the weight of the acrylic resin as Y, X/(X+Y) is 0.3 or more and less than 0.9.

9. A dicing die bond film, wherein the thermosetting type die bond film according to claim 1 is laminated on a dicing film in which a pressure-sensitive adhesive layer is laminated on a base.

10. A method of manufacturing a semiconductor device using the dicing die bond film according to claim 9, comprising the steps of:
forming a reforming region on predetermined dividing lines by irradiating the predetermined dividing lines of the semiconductor wafer with a laser beam,
pasting the semiconductor wafer after the formation of the reforming region to the dicing die bond film,
forming a semiconductor element by breaking the semiconductor wafer and the die bond film that constitutes the dicing die bond film together at the predetermined dividing lines by applying tensile force to the dicing die bond film so that the expansion speed becomes 100 to 400 mm/sec and the expansion amount becomes 6 to 12% under a condition of 0 to 25° C.,
picking up the semiconductor element together with the die bond film, and
die bonding the picked up semiconductor element to an adherend with the die bond film in between.

11. A method of manufacturing a semiconductor device using the dicing die bond film according to claim 9, comprising the steps of:
forming grooves that do not reach the backside of the semiconductor wafer on a surface thereof,
exposing the grooves from the backside by grinding the backside of the semiconductor wafer,
pasting the semiconductor wafer with the grooves exposed from the backside to the dicing die bond film,
forming a semiconductor element by breaking the die bond film that constitutes the dicing die bond film by applying tensile force to the dicing die bond film so that the expansion speed becomes 100 to 400 mm/sec and the expansion amount becomes 6 to 12% under a condition of 0 to 25° C.,
picking up the semiconductor element together with the die bond film, and
die bonding the picked up semiconductor element to an adherend with the die bond film in between.

12. A thermosetting die bond film, wherein the pre-thermal curing elongation rate at break at 25° C. is larger than 40% and 500% or less.
